(19) United States
(12) Patent Application Publication
(10) Pub. No.: US 2025/0183052 A1
(43) Pub. Date: Jun. 5, 2025

(54) PROCESSING METHOD AND PROCESSING SYSTEM

(71) Applicant: Tokyo Electron Limited, Tokyo (JP)

(72) Inventor: Mitsuhiro TACHIBANA, Nirasaki City (JP)

(21) Appl. No.: 19/048,079

(22) Filed: Feb. 7, 2025

Related U.S. Application Data
(63) Continuation of application No. PCT/JP2023/041243, filed on Nov. 16, 2023.

(30) Foreign Application Priority Data
Nov. 29, 2022 (JP) 2022-190509

(51) Int. Cl. H01L 21/311; C09K 13/08; H01L 21/67

(52) U.S. Cl. CPC H01L 21/31116; C09K 13/08; H01L 21/67069

(57) ABSTRACT

A processing method of selectively etching an oxygen-containing film in a substrate having the oxygen-containing film and a nitrogen-containing film formed on a surface of the substrate, wherein the method includes: forming an ammonium fluorosilicate layer by selectively modifying the oxygen-containing film with respect to the nitrogen-containing film by using process gases including a fluorine-containing gas and a hydrazine-based gas; and removing the ammonium fluorosilicate layer by heating the substrate.

### CROSS-REFERENCE TO RELATED APPLICATION

The application is a Bypass Continuation Application of PCT International Application No. PCT/JP2023/041243, filed on Nov. 16, 2023 and designating the United States, the international application being based upon and claiming the benefit of priority from Japanese Patent Application No. 2022-190509, filed on Nov. 29, 2022, the entire content of which is incorporated herein by reference.

### TECHNICAL FIELD

The present disclosure relates to a processing method and a processing system.

### BACKGROUND

Patent Document 1 discloses that a silicon-containing film formed on a substrate surface is selectively removed by sequentially performing a chemical oxide removal (COR) process using ammonia (NH₃) gas and hydrogen fluoride (HF) gas as a process gas, and a post heat treatment (PHT) process.

### Prior Art Document

### Patent Document

Patent Document 1: Japanese Patent Laid-open Publication No. 2018-032720

### SUMMARY

According to one embodiment of the present disclosure, there is provided a processing method of selectively etching an oxygen-containing film on a substrate having the oxygen-containing film and a nitrogen-containing film formed on the surface of the substrate, the processing method including: selectively altering the oxygen-containing film relative to the nitrogen-containing film, using a processing gas that includes a fluorine-containing gas and a hydrazine-based gas, to form a ammonium fluorosilicate layer; and heating the substrate to remove the ammonium fluorosilicate layer.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view showing an example of s configuration of a processing system according to the present embodiment.

FIG. 2 is a longitudinal cross-sectional view showing an example of a configuration of a COR module according to the present embodiment.

FIG. 3 is a graph showing a relationship between an etching amount of an oxygen-containing film and a processing time.

FIG. 4 is a graph showing a relationship between an etching amount of a nitrogen-containing film and a processing time.

FIG. 5 is a graph showing a comparison between Gibbs free energies relating to an oxygen-containing film.

FIG. 6 is a table showing etching amounts of an oxygen-containing film and a nitrogen-containing film according to Example and Comparative Example.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a manufacturing process of semiconductor devices, an oxygen-containing film (e.g., a SiO film or a SiO₂ film) formed on a surface of a semiconductor substrate (hereinafter simply referred to as a “substrate”) is selectively etched with respect to a nitrogen-containing film (e.g., a SiN film). The selective etching of the oxygen-containing film is implemented by, for example, as disclosed in Patent Document 1, sequentially performing a COR process and a PHT process on the substrate.

In the COR process, for example, NH₃ gas and HF gas are used as a process gas to modify a surface of the oxygen-containing film as an etching target into ammonium fluorosilicate (AFS).

In the PHT process, the AFS formed on the surface of the oxygen-containing film in the COR process is sublimated by heating.

However, in such selective etching of the oxygen-containing film, there is a demand for further efficiency in the etching process, specifically, improvement in an etching rate of the oxygen-containing film and a selectivity to the nitrogen-containing film. In general, an etching rate in an etching process tends to be improved by heating a substrate W or increasing an atmospheric temperature, but NH₃ gas used as the aforementioned process gas has a problem that an etching rate is not stable in a high temperature range. In other words, there is room for improvement in the conventional selective etching of the oxygen-containing film.

The technique disclosed in the present disclosure has been made in consideration of the above circumstances. With this technique, in processing a substrate having an oxygen-containing film and a nitrogen-containing film formed on a surface thereof, selective etching of the oxygen-containing film is appropriately performed with respect to the nitrogen-containing film. Hereinafter, a substrate processing method according to the present embodiment will be described with reference to the drawings. Throughout this specification and the drawings, elements having substantially the same functional configuration are denoted by the same reference numerals, and therefore, duplicated explanation thereof will be omitted.

### Processing System

First, a configuration of a processing system according to an embodiment will be described.

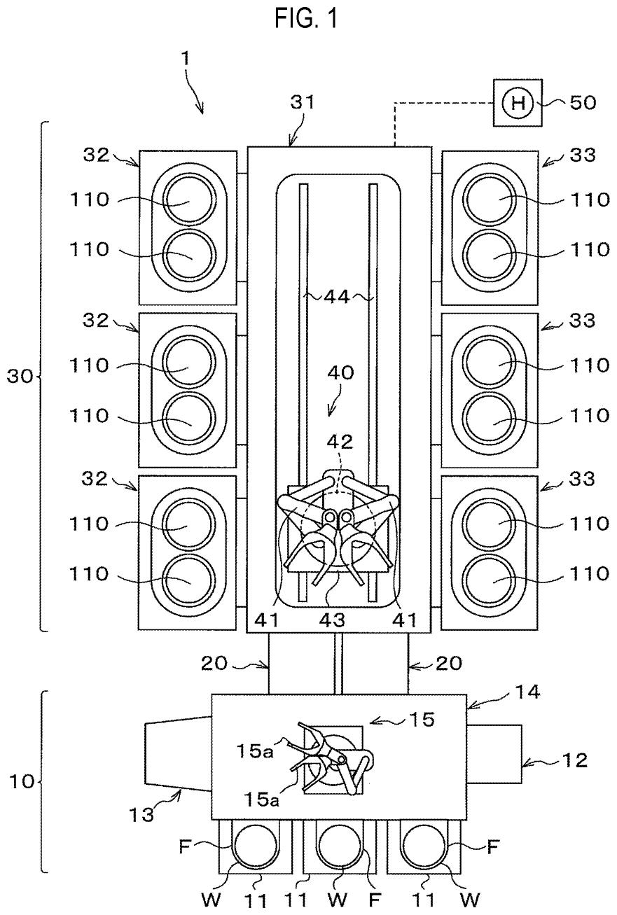

As shown in FIG. 1, a processing system 1 has a configuration in which an atmospheric part 10 and a depressurized part 30 are integrally connected via load lock modules 20.

The atmospheric part 10 has load ports 11 on each of which a front opening unified pods (FOUP) F capable of storing a plurality of substrates W is placed, a cooling storage 12 configured to cool the substrates W after processing in the depressurized part 30, an aligner module 13 configured to adjust a horizontal orientation of the substrates W, and a loader module 14 configured to transfer the substrates W within the atmospheric part 10.

The cooling storage 12 cools the substrates W after a COR process and a PHT process are performed in the depressurized part 30 to be described later.

The aligner module 13 adjusts the horizontal orientation of the substrates W after being unloaded from the FOUP F and before being transferred to the depressurized part 30 to be described later.

The loader module 14 is formed of a housing having a rectangular internal space, and an interior of the housing is maintained at atmospheric pressure. A plurality of load ports 11, for example, three load ports 11, are arranged side by side on one side of the loader module 14 that constitutes a long side of the housing. A plurality of load lock modules 20, for example, two load lock modules 20, are arranged side by side on the other side of the loader module 14 that constitutes a long side of the housing. The cooling storage 12 is provided on one side of the loader module 14 that constitutes a short side of the housing. The aligner module 13 is provided on the other side of the loader module 14 that constitutes a short side of the housing.

In addition, a substrate transfer mechanism 15 configured to transfer the substrate W is provided in the loader module 14. The substrate transfer mechanism 15 has transfer arms 15a that hold and move the substrate W, and is configured to be capable of transferring the substrate W with respect to each of the FOUPs F placed on the load ports 11, the cooling storage 12, the aligner module 13, and the load lock modules 20.

Each load lock module 20 temporarily holds the substrate W transferred from the loader module 14 of the atmospheric part 10 in order to deliver the substrate W to a transfer module 31, which will be described later, of the depressurized part 30. Each load lock module 20 has a plurality of stockers, for example, two stockers (not shown) therein, so that two substrates W are held in each load lock module 20 at the same time.

A gas introducer (not shown) and a gas discharger (not shown) are connected to each load lock module 20, so that each load lock module 20 is configured to be switchable between an atmospheric atmosphere and a depressurized atmosphere. In addition, each load lock module 20 has a gate valve (not shown) for ensuring airtightness with respect to each of the loader module 14 and the transfer module 31 which will be described later. By the gate valve, both airtightness and communication between the loader module 14 and the transfer module 31 are ensured. In other words, each load lock module 20 is configured to be capable of delivering the substrate W appropriately between the atmospheric part 10 under the atmospheric atmosphere and the depressurized part 30 under the depressurized atmosphere.

The depressurized part 30 has the transfer module 31 that transfers two substrates W simultaneously, COR modules 32 each of which performs a COR process on the substrates W loaded from the transfer module 31, and PHT modules 33 each of which performs a PHT process on the substrates W after the COR process. Interiors of the transfer module 31, the COR modules 32, and the PHT modules 33 are each maintained in a depressurized atmosphere. In addition, a plurality of COR modules 32 and PHT modules 33, for example, three COR modules 32 and three PHT modules 33, are provided for the transfer module 31.

The transfer module 31 has a housing having a rectangular internal space, and is connected to each of the load lock modules 20 via the gate valves, as described above. The transfer module 31 transfers the substrates W loaded into the load lock module 20 to one COR module 32 and one PHT module 33, where the substrates W are sequentially subjected to the COR process and the PHT process, and then unloads the substrates W to the atmospheric part 10 via the load lock module 20.

A substrate transfer mechanism 40 configured to transfer the substrate W is provided in the transfer module 31. The substrate transfer mechanism 40 has transfer arms 41 configured to hold and move two substrates W, a rotary table 42 configured to rotatably support the transfer arms 41, and a rotary stage 43 on which the rotary table 42 is placed. In addition, a guide rail 44 extending in a longitudinal direction of the transfer module 31 is provided in the transfer module 31. The rotary stage 43 is provided on the guide rail 44, and is configured to be capable of moving the substrate transfer mechanism 40 along the guide rail 44.

In the COR module 32 as a formation device, of an oxygen-containing film (e.g., a SiO film or a SiO₂ film) and a nitrogen-containing film (e.g., a SiN film) formed on a surface of the substrate W to be processed, a surface of the oxygen-containing film is selectively modified to form an ammonium fluorosilicate (AFS) layer as a reaction product on the surface of the oxygen-containing film.

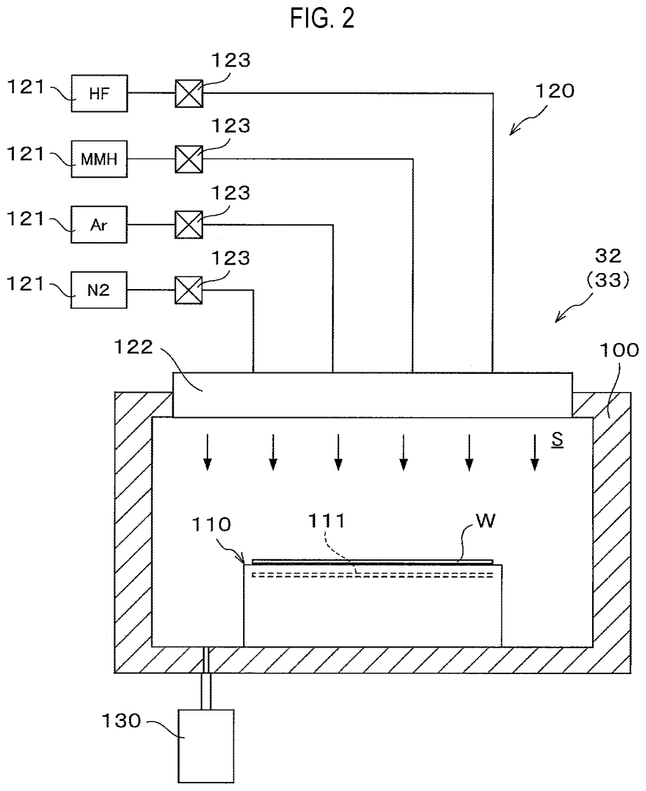

As shown in FIG. 2, the COR module 32 includes a sealed process container 100 that accommodates the substrate W, and a processing space S is formed in the process container 100. A load/unload port (not shown) for the substrate W is provided on a side surface of the process container 100, and the process container 100 is in communication with the interior of the transfer module 31 via the load/unload port. The load/unload port is configured to be opened and closed by a gate valve (not shown), thereby ensuring both airtightness and communication between the transfer module 31 and the COR module 32. In addition, the transfer module 31 is provided with a stage 110 configured to place the substrate W thereon in the process container 100, a supply 120 configured to supply a process gas into the processing space S, and an exhauster 130 configured to exhaust the process gas from the process container 100.

The stage 110 is provided to be fixed to a bottom surface of the process container 100, and a holding surface for holding the substrate W is formed on an upper surface of the stage 110. A temperature adjustment mechanism 111 configured to adjust a temperature of the substrate W on the holding surface is provided in the stage 110.

In addition, as shown in FIG. 1, the COR module 32 has two stages 110 on which two substrates W are placed side by side in a horizontal direction, and is configured to perform the COR process on the two substrates W simultaneously, but in order to avoid the illustration from becoming complicated, only one stage 110 is shown in FIG. 2.

The supply 120 has a plurality of gas sources 121 configured to supply a fluorine-containing gas (e.g., HF gas), a hydrazine-based gas (e.g., hydrazine or monomethylhydrazine (MMH)), a dilution gas (e.g., Ar gas), and an inert gas (e.g., N₂ gas), respectively, as process gases into the process container 100, and a shower head 122 provided on a ceiling of the process container 100 and having a plurality of discharge ports for discharging the process gases into the processing space S. The gas sources 121 are connected to an interior of the process container 100 via supply pipes connected to the shower head 122.

In addition, the supply 120 is provided with flow rate regulators 123 configured to regulate supply amounts of the process gases into the interior of the process container 100. Each flow rate regulator 123 has, for example, an opening/closing valve and a mass flow controller.

The exhauster 130 is connected to an exhaust mechanism (not shown), such as a vacuum pump, via an exhaust pipe provided at a bottom portion of the process container 100. In addition, an automatic pressure control (APC) valve is provided in the exhaust pipe. An internal pressure of the process container 100 is controlled by the exhaust mechanism and the APC valve.

In addition, the COR module 32 is provided with a control device (not shown) configured to control the COR process performed in the COR module 32. The control device may be the same as a control device 50, which will be described later, provided in the processing system 1, or may one that is connected to the COR module 32 independently.

In addition, in the COR module 32 according to the technique of the present disclosure, as described above, a hydrazine-based gas having a strong reducing power is used as the process gas. From this point of view, it is necessary to perform surface treatment (coating treatment or thermal spraying treatment) to prevent influence of the hydrazine-based gas on the interior of the COR module 32, particularly on surfaces of the process container 100, the shower head 122, and the stage 110, which form the processing space S.

In the PHT module 33 as a removal device, the AFS formed on the surface of the substrate W to be processed in the COR module 32 is sublimated by heating. That is, in the depressurized part 30 of the processing system 1 in the present embodiment, the COR process (selective formation of AFS on the oxygen-containing film) and the PHT process (sublimation of the AFS) are sequentially performed on the substrate W to be processed, thereby selectively removing the oxygen-containing film of the oxygen-containing film and the nitrogen-containing film formed on the surface of the substrate W to be processed.

The PHT module 33 has the same configuration as, for example, that of the COR module 32 shown in FIG. 2. That is, the PHT module 33 includes a process container 100 having a processing space S formed therein, a stage 110 configured to place the substrate W in the process container 100, a supply 120 configured to supply process gases into the process container 100, and an exhauster 130 configured to exhaust the process gases in the process container 100.

In addition, as shown in FIG. 1, the PHT module 33 is provided with two stages 110 on which two substrates W are placed side by side in the horizontal direction, and is configured to perform the PHT process on the two substrates W simultaneously.

In addition, as described above, since the COR module 32 and the PHT module 33 in one example have the same configuration, the PHT process may be performed in the COR module 32. In other words, the COR module 32 and the PHT module 33 may be configured as one unit, and the COR process and the PHT process may be performed in the same substrate processing module (not shown). That is, in the technique according to the present disclosure, the COR module 32 as a formation device and the PHT module 33 as a removal device may be configured as one unit.

The processing system 1 described above is provided with the control device 50. The control device 50 is, for example, a computer equipped with a CPU, a memory, and the like, and has a program storage (not shown). The program storage stores a program for controlling the processing and transfer of the substrate W in the processing system 1. The program may be recorded in a computer-readable storage medium H and installed in the control device 50 from the storage medium H. The storage medium H may be transitory or non-transitory.

The processing system 1 according to the present embodiment is configured as described above as an example, but the configuration of the processing system is not limited thereto.

For example, as described above, in the embodiment, the processing system 1 is configured to be capable of processing and transferring two substrates W simultaneously, but the process and transfer of substrates W may be performed sheet by sheet, or three or more substrates W may be processed and transferred simultaneously.

### Processing Method

Next, details of a method of processing substrates W using the depressurized part 30 of the processing system 1 configured as described above, that is, the COR process and the PHT process, will be described.

Prior to the COR process and the PHT process, the oxygen-containing film (SiO film as an example in the following description) and the nitrogen-containing film (SiN film as an example in the following description) as described above are formed in advance on the surface of the substrate W to be processed in the processing system 1.

In the COR process in the COR module 32, the surface of the SiO film formed on the surface of the substrate W to be processed is modified to form an AFS layer on the surface of the SiO film.

In the COR process according to the present embodiment, first, the substrate W to be processed is placed on the stage 110 of the COR module 32. Subsequently, a dilution gas (Ar gas) and an inert gas (N₂ gas) are supplied into the sealed process container 100. Then, the internal pressure of the process container 100 is controlled to be, for example, 300 mTorr to 30 Torr, and the temperature of the substrate W on the stage 110 is controlled to be, for example, 0 degrees C. to 150 degrees C., specifically, 30 degrees C. to 120 degrees C.

When the internal pressure of the processing space S and the temperature of the substrate W reach a desired state, subsequently, a fluorine-containing gas (HF gas in the present embodiment) and a hydrazine-based gas (MMH gas in the present embodiment) are supplied into the processing space S. At this time, a flow rate of each of the HF gas and the MMH gas supplied into the processing space S is controlled to be, for example, 50 sccm to 500 sccm, and a flow rate of each of the Ar gas and the N₂ gas is controlled to be, for example, 100 sccm to 600 sccm. Then, the HF gas and the MMH gas supplied into the processing space S as described above are caused to act on the SiO film formed on the surface of the substrate W, thereby forming an AFS layer, which is a reaction product, on the surface layer of the SiO film.

When the SiO film is modified by the COR process to form the AFS layer, subsequently, the AFS layer is removed by sublimation using the PHT module 33.

In the PHT process according to the present embodiment, first, the substrate W that has been subjected to the COR process is placed on the stage 110 of the PHT module 33. Subsequently, an inert gas (N₂ gas) is supplied into the sealed process container 100, and the substrate W on the stage 110 is controlled to be, for example, 85 degrees C. or higher. Since AFS, which is a reaction product formed by the COR process, is sublimated by heat, by increasing the temperature of the substrate W as described above, the AFS layer formed by the COR process, i.e., the modified SiO film, can be sublimated and removed. The sublimated AFS is recovered in the exhauster 130 together with, for example, the inert gas (N₂ gas).

In addition, modifying the SiO film (the formation of the AFS layer) in the COR module 32 and removing the SiO film (the sublimation of the AFS layer) in the PHT module 33 may be repeated alternately until a desired amount of removal (etching) is obtained for the SiO film formed on the substrate W.

When the desired amount of removal (etching) is obtained for the SiO film formed on the substrate W as described above, a series of selectively etching the SiO film (the oxygen-containing film) according to the present embodiment is completed.

### Operative Effects of Substrate Processing Method According to Present Embodiment

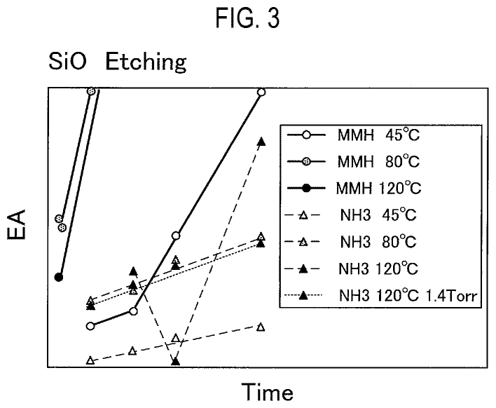

FIG. 3 is a graph showing a relationship between a processing time and an etching amount (EA) of the oxygen-containing film (SiO film) for each temperature of the substrate W during the COR process, when the monomethylhydrazine (MMH) gas and the ammonia (NH₃) gas were used as the process gases in the COR process.

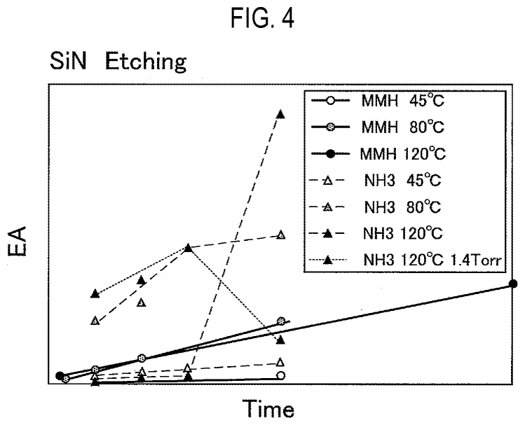

FIG. 4 is a graph showing a relationship between a processing time and an etching amount (EA) of the nitrogen-containing film (SiN film) for each temperature of the substrate W during the COR process, when the monomethylhydrazine (MMH) gas and the ammonia (NH₃) gas were used as the process gases.

Further, the etching amount (EA) referred to herein can be expressed in other words as an amount of modification of the oxygen-containing film (SiO film) or the nitrogen-containing film (SiN film) (an amount of formation of the AFS layer) in the COR process.

As shown in FIG. 3, the amount of etching of the SiO film was larger when the MMH gas was used in the COR process, compared to a case in which the NH₃ gas was used. In other words, it has been recognized that by using the MMH gas, it is possible to improve an etching rate of the SiO film compared to a case of using the NH₃ gas.

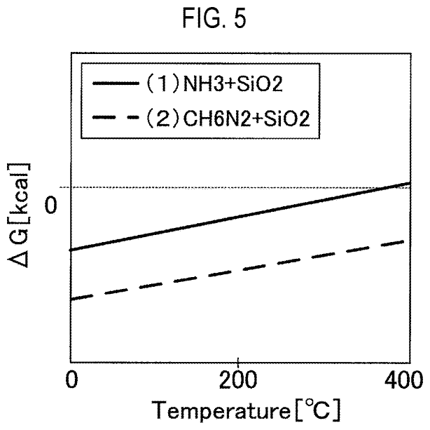

The reason is because, as shown in FIG. 5, an AFS formation power ΔG [kcal/mol] (in the example of FIG. 5, an absolute value of ΔG which indicates the Gibbs free energy) of the MMH gas ((2) in the figure) is larger than that of the NH₃ gas ((1) in the figure).

On the other hand, as shown in FIG. 4, the amount of etching of the SiN film was smaller when the MMH gas was used in the COR process, compared to a case in which the NH₃ gas was used. In other words, it has been recognized that by using the MMH gas, it is possible to improve to the etching rate of the SiO film shown in FIG. 3 and to improve an etching selectivity of the SiO film, compared to a case of using the NH₃ gas.

It is considered that the reason is because the MMH gas has a greater nitriding power for silicon than the NH₃ gas and thus reduces consumption of the SiN film. As a result of review by the present inventor, it has been recognized that the MMH gas has about twice the nitriding power as the NH₃ gas.

In addition, as shown in FIGS. 3 and 4, in particular, when the COR process was performed in a high-temperature environment (120 degrees C. in the illustrated example), the etching amount with respect to the processing time was not stable (the etching amount changed irregularly) when the NH₃ gas was used, whereas the etching amount was stable (the etching amount changed linearly) when the MMH gas was used.

It is considered that the reason is because an adsorption power of the MMH gas is greater than the NH₃ gas. As described above, since the etching of the SiO film according to the present embodiment is a dry process, an adsorption power of the process gas is important. Therefore, by using the MMH gas, which has the greater adsorption power than the NH₃ gas, the etching process of the SiO film can proceed stably regardless of a temperature.

As can be recognized from the results shown in FIGS. 3 and 4 described above, when performing the COR process on the substrate W, by using a hydrazine-based gas (the MMH gas in the above-described embodiment) instead of ammonia (NH₃) gas which has been mainly used in the conventional selective etching, the selective etching of the oxygen-containing film with respect to the nitrogen-containing film can be performed appropriately.

Specifically, as described above, in the etching process, the etching rate of the oxygen-containing film and the selectivity of the oxygen-containing film with respect to the nitrogen-containing film can be improved.

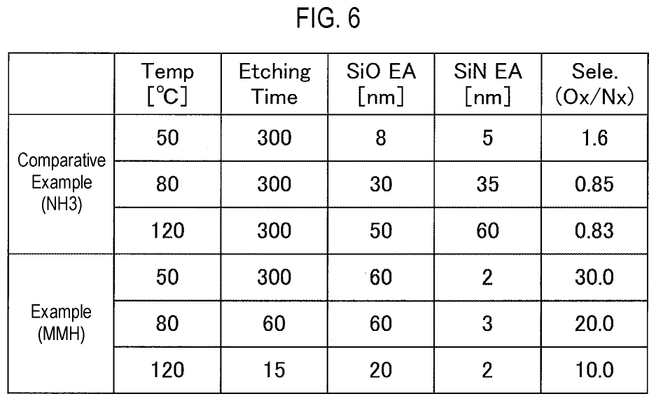

FIG. 6 is a table showing an etching amount (EA) and a selectivity (Sele.) in each case of using monomethylhydrazine (MMH) gas (Example) and using ammonia (NH₃) gas (Comparative Example) as the process gases in the COR process.

As shown in FIG. 6, in Comparative Example using the NH₃ gas as the process gas, the selectivity of the etching amount of the oxygen-containing film (SiO film) with respect to the nitrogen-containing film (SiN film) was 1.6, 0.85, and 0.83 when the temperature of the substrate W was 50 degrees C., 80 degrees C., and 120 degrees C., respectively.

In contrast, in Example using the MMH gas as the process gas, the selectivity of the etching amount of the oxygen-containing film (SiO film) with respect to the nitrogen-containing film (SiN film) was 30.0, 20.0, and 10.0 when the temperatures of the substrate W was 50 degrees C., 80 degrees C., and 120 degrees C., respectively, which is a significant improvement in selectivity over Comparative Example.

In addition, as shown in FIG. 6, in Example using the MMH gas as the process gas, the etching processing time was set to be short when the temperature of the substrate W was 80 degrees C. and 120 degrees C. Specifically, in both cases of using the NH₃ gas and using the MMH gas, the etching processing time was 300 seconds when the temperature of the substrate W was 50 degrees C. On the other hand, the etching processing time was 60 seconds when the temperature of the substrate W was 80 degrees C. and the etching processing time was 15 seconds when the temperature of the substrate W is 120 degrees C. Even in such cases, the etching amount of the oxygen-containing film can be ensured appropriately.

That is, it can be recognized that even in an etching process with a short period of time, an etching amount (etching rate) of the oxygen-containing film can be increased compared to a case of using the NH₃ gas, and by setting an etching processing time to be long, an etching amount and a selectivity of the oxygen-containing film can be further improved.

In addition, according to the present embodiment, since the etching rate of the oxygen-containing film changes linearly with respect to the processing time as described above, it is possible to stabilize a result of the etching process for the substrate W. In other words, a desired etching amount of the oxygen-containing film can be obtained easily by controlling a processing time.

In addition, according to the present embodiment, etching the oxygen-containing film can be appropriately performed regardless of a temperature, especially in a high-temperature environment.

In addition, it is known that in general, hydrazine-based gases have high reactivity and cause generation of particles when used simultaneously with, for example, silane-based gases or metal-containing gases.

In this regard, since the process gas used simultaneously with the hydrazine-based gas in the COR process according to the present disclosure is a fluorine-containing gas (the HF gas in the above-described embodiment) and the COR process is performed at a relatively low temperature, reactions, which generate particles as in the aforementioned cases of using the silane-based gases or the metal-containing gases, are suppressed.

In addition, in the above-described embodiment, the case in which the oxygen-containing film is a SiO film and the nitrogen-containing film is a SiN film has been described as an example, but types of the oxygen-containing film and the nitrogen-containing film formed on the substrate W are not limited thereto.

Specifically, as the nitrogen-containing film as a non-etching target, instead of the SiN film, a metal nitride film such as TiN or TaN may be formed on the substrate W.

In addition, in the above-described embodiment, the HF gas and the MMH gas are used as the process gases for the COR process, but types of the process gases used for the COR process are not limited thereto.

Specifically, as the hydrazine-based gas used for the COR process, for example, hydrazine gas or dimethylhydrazine gas may be used instead of the monomethylhydrazine (MMH) gas.

The embodiments disclosed herein should be considered as illustrative and not restrictive in all respects. The above-described embodiments may be omitted, substituted, or modified in various forms without departing from the scope and spirit of the accompanying claims. For example, components of the above-described embodiments may be arbitrarily combined. From such an arbitrary combination, operations and effects of each of the components related to the combination can be obtained as a matter of course, and other operations and effects that are obvious to those skilled in the art from the description of this specification can be obtained.

In addition, the effects described in this specification are merely explanatory or illustrative and are not restrictive. That is, the technique according to the present disclosure may provide other effects that are obvious to those skilled in the art from the description of this specification, in addition to or in place of the above-described effects.

In addition, the following configurations also fall within the technical scope of the present disclosure.

(1) A processing method of selectively etching an oxygen-containing film in a substrate having the oxygen-containing film and a nitrogen-containing film formed on a surface of the substrate, including: forming an ammonium fluorosilicate layer by selectively modifying the oxygen-containing film with respect to the nitrogen-containing film by using process gases including a fluorine-containing gas and a hydrazine-based gas; and removing the ammonium fluorosilicate layer by heating the substrate.

(2) The processing method of (1), wherein the hydrazine-based gas includes at least one gas selected from hydrazine, monomethylhydrazine, or dimethylhydrazine.

(3) The processing method of (1) or (2), wherein in the forming the ammonium fluorosilicate layer, a temperature of the substrate is controlled to be 30 degrees C. to 120 degrees C.

(4) The processing method of any one of (1) to (3), wherein the forming the ammonium fluorosilicate layer and the removing the ammonium fluorosilicate layer are repeated alternately.

(5) A processing system for processing a substrate having an oxygen-containing film and a nitrogen-containing film formed on a surface of the substrate, including: a formation device configured to form an ammonium fluorosilicate layer; a removal device configured to remove the ammonium fluorosilicate layer; and a control device, wherein the control device controls the formation device and the removal device to execute: forming the ammonium fluorosilicate layer in the formation device by selectively modifying the oxygen-containing film with respect to the nitrogen-containing film by using process gases including a fluorine-containing gas and a hydrazine-based gas; and removing the ammonium fluorosilicate layer in the removal device by heating the substrate.

(6) The processing system of (5), wherein the hydrazine-based gas includes at least one gas selected from hydrazine, monomethylhydrazine, or dimethylhydrazine.

(7) The processing system of (5) or (6), wherein the formation device includes: a stage having a placement surface on which the substrate is placed; and a heating mechanism configured to heat the substrate on the placement surface, and wherein the control device controls the heating mechanism to set a temperature of the substrate to be 30 degrees C. to 120 degrees C. in the forming the ammonium fluorosilicate layer.

(8) The processing system of any one of (5) to (7), wherein the formation device and the removal device are configured as one unit.

According to the present disclosure, in processing a substrate having an oxygen-containing film and a nitrogen-containing film formed on a surface thereof, it is possible to appropriately perform selective etching of the oxygen-containing film with respect to the nitrogen-containing film.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A processing method of selectively etching an oxygen-containing film in a substrate having the oxygen-containing film and a nitrogen-containing film formed on a surface of the substrate, comprising:
forming an ammonium fluorosilicate layer by selectively modifying the oxygen-containing film with respect to the nitrogen-containing film by using process gases including a fluorine-containing gas and a hydrazine-based gas; and
removing the ammonium fluorosilicate layer by heating the substrate.

2. The processing method of claim 1, wherein the hydrazine-based gas includes at least one gas selected from hydrazine, monomethylhydrazine, or dimethylhydrazine.

3. The processing method of claim 2, wherein in the forming the ammonium fluorosilicate layer, a temperature of the substrate is controlled to be 30 degrees C. to 120 degrees C.

4. The processing method of claim 1, wherein in the forming the ammonium fluorosilicate layer, a temperature of the substrate is controlled to be 30 degrees C. to 120 degrees C.

5. The processing method of claim 1, wherein the forming the ammonium fluorosilicate layer and the removing the ammonium fluorosilicate layer are repeated alternately.

6. A processing system for processing a substrate having an oxygen-containing film and a nitrogen-containing film formed on a surface of the substrate, comprising:
a formation device configured to form an ammonium fluorosilicate layer;
a removal device configured to remove the ammonium fluorosilicate layer; and
a control device,
wherein the control device controls the formation device and the removal device to execute:
forming the ammonium fluorosilicate layer in the formation device by selectively modifying the oxygen-containing film with respect to the nitrogen-containing film by using process gases including a fluorine-containing gas and a hydrazine-based gas; and
removing the ammonium fluorosilicate layer in the removal device by heating the substrate.

7. The processing system of claim 6, wherein the hydrazine-based gas includes at least one gas selected from hydrazine, monomethylhydrazine, or dimethylhydrazine.

8. The processing system of claim 7, wherein the formation device includes:
a stage having a placement surface on which the substrate is placed; and
a heating mechanism configured to heat the substrate on the placement surface, and
wherein the control device controls the heating mechanism to set a temperature of the substrate to be 30 degrees C. to 120 degrees C. in the forming the ammonium fluorosilicate layer.

9. The processing system of claim 6, wherein the formation device includes:
a stage having a placement surface on which the substrate is placed; and
a heating mechanism configured to heat the substrate on the placement surface, and
wherein the control device controls the heating mechanism to set a temperature of the substrate to be 30 degrees C. to 120 degrees C. in the forming the ammonium fluorosilicate layer.

10. The processing system of claim 6, wherein the formation device and the removal device are configured as one unit.
